(19) United States
(12) Patent Application Publication
(10) Pub. No.: US 2022/0122859 A1
(43) Pub. Date: Apr. 21, 2022

(54) METHOD OF MANUFACTURING SEMICONDUCTOR DEVICE AND APPARATUS FOR MANUFACTURING SEMICONDUCTOR DEVICE

(71) Applicants: KOKUSAI ELECTRIC CORPORATION, Tokyo (JP); OSAKA GAS CO., LTD., Osaka (JP)

(72) Inventors: Hitoshi MURATA, Toyama-shi (JP); Yasuo KUNII, Toyama-shi (JP); Masaaki UENO, Toyama-shi (JP); Masahiro SUEMITSU, Toyama-shi (JP)

(73) Assignees: KOKUSAI ELECTRIC CORPORATION, Tokyo (JP); OSAKA GAS CO., LTD., Osaka (JP)

(21) Appl. No.: 17/563,475

(22) Filed: Dec. 28, 2021

Related U.S. Application Data
(63) Continuation of application No. PCT/JP2020/029325, filed on Jul. 30, 2020.

(30) Foreign Application Priority Data
Aug. 30, 2019 (JP) 2019-158467

(51) Int. Cl. H01L 21/67; H01L 21/324

(52) U.S. Cl. CPC H01L 21/67115; H01L 21/324

(57) ABSTRACT

There is provided a technique that includes a quartz container in which an object to be processed, which contains a semiconductor, is arranged; a heater configured to emit heat; and a radiation control body arranged between the quartz container and the heater, wherein the radiation control body is configured to radiate a radiant wave of a wavelength transmittable through the quartz container by heating from the heater such that the radiant wave reaches the object to be processed in the quartz container.

### CROSS-REFERENCE TO RELATED APPLICATION

This application is a Bypass Continuation Application of PCT International Application No. PCT/JP2020/029325, filed on Jul. 30, 2020 and designating the United States, the international application being based upon and claiming the benefit of priority from Japanese Patent Application No. 2019-158467, filed on Aug. 30, 2019, the entire contents of which are incorporated herein by reference.

### TECHNICAL FIELD

The present disclosure relates to a method of manufacturing a semiconductor device and an apparatus for manufacturing a semiconductor device.

### BACKGROUND

For example, in a process of manufacturing a semiconductor device, a vertical substrate processing apparatus (hereinafter, also referred to as a “vertical apparatus”) may be used as an apparatus for processing a semiconductor wafer (hereinafter, also simply referred to as a wafer), which is an object to be processed, containing a semiconductor. The vertical apparatus is configured to heat the wafers to a predetermined temperature for processing by radiating a radiant wave from a heater arranged on the outer peripheral side of the quartz reaction container and causing the radiant wave transmitted through the quartz reaction container to reach the wafers, in a state where a substrate holder (boat) for holding a plurality of wafers in multiple stages is accommodated in a quartz reaction container (hereinafter, also referred to as a “quartz reaction tube”, and simply abbreviated as a “quartz tube”).

In the vertical apparatus of the above-described configuration, due to that a wavelength of the radiant wave from the heater, a wavelength transmittable through the quartz reaction tube, and a wavelength absorbed by the wafers are different from each other, a processing for the wafers may not be performed efficiently and appropriately.

### SUMMARY

Some embodiments of the present disclosure provide a technique capable of efficiently and appropriately processing an object to be processed.

According to one embodiment of the present disclosure, there is provided a technique that includes a quartz container in which an object to be processed, which contains a semiconductor, is arranged; a heater configured to emit heat; and a radiation control body arranged between the quartz container and the heater, wherein the radiation control body is configured to radiate a radiant wave of a wavelength transmittable through the quartz container by heating from the heater such that the radiant wave reaches the object to be processed in the quartz container.

### BRIEF DESCRIPTION OF DRAWINGS

The accompanying drawings, which are incorporated in and constitute a part of the specification, illustrate embodiments of the present disclosure.

FIG. 1 is a side sectional view schematically showing a schematic configuration example of a semiconductor manufacturing apparatus according to a first embodiment of the present disclosure.

FIG. 2 is a side sectional view schematically showing an example of a radiation control body in the semiconductor manufacturing apparatus according to the first embodiment of the present disclosure.

FIG. 3 is a conceptual diagram schematically showing an example of heat radiation control by a heating structure of the semiconductor manufacturing apparatus according to the first embodiment of the present disclosure.

FIG. 4 is a side sectional view schematically showing a configuration example of a semiconductor manufacturing apparatus according to a second embodiment of the present disclosure.

FIGS. 5A and 5B are explanatory diagrams schematically showing an arrangement example of a radiation control body in a semiconductor manufacturing apparatus according to another embodiment of the present disclosure.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments of the present disclosure will be described with reference to the drawings.

A substrate processing apparatus given as an example in the following embodiments is used in a process of manufacturing a semiconductor device, and is configured as a vertical substrate processing apparatus that collectively processes a plurality of semiconductor substrates, which are objects to be processed, including a semiconductor.

An example of the semiconductor substrate (wafer), which is the object to be processed, including a semiconductor, may include a semiconductor wafer, a semiconductor package, or the like in which a semiconductor integrated circuit device is built. In addition, when the term “wafer” is used in the present disclosure, it may mean a “wafer itself” or “wafer and a laminate (aggregate) of certain layers or films, etc. formed on the surface thereof” (that is, a wafer including a certain layer, film, etc. formed on the surface thereof). Further, when the term “surface of a wafer ” is used in the present disclosure, it may mean a “surface (exposed surface) of a wafer itself” or a “surface of a certain layer or film formed on the wafer, that is, the outermost surface of the wafer as a laminate.”

Further, a process performed by the substrate processing apparatus on the wafer may be any process performed by heating the wafer to a predetermined temperature, for example, an oxidation process, a diffusion process, a reflow or annealing process for carrier activation or planarization after ion doping, a film-forming process, etc. In particular, the present embodiment takes the film-forming process as an example. Further, an apparatus for manufacturing the semiconductor device may be referred to as a semiconductor device manufacturing apparatus which is a kind of substrate processing apparatus.

### First Embodiment

First, a first embodiment of the present disclosure is specifically described.

### (1) Configuration of Reaction Tube

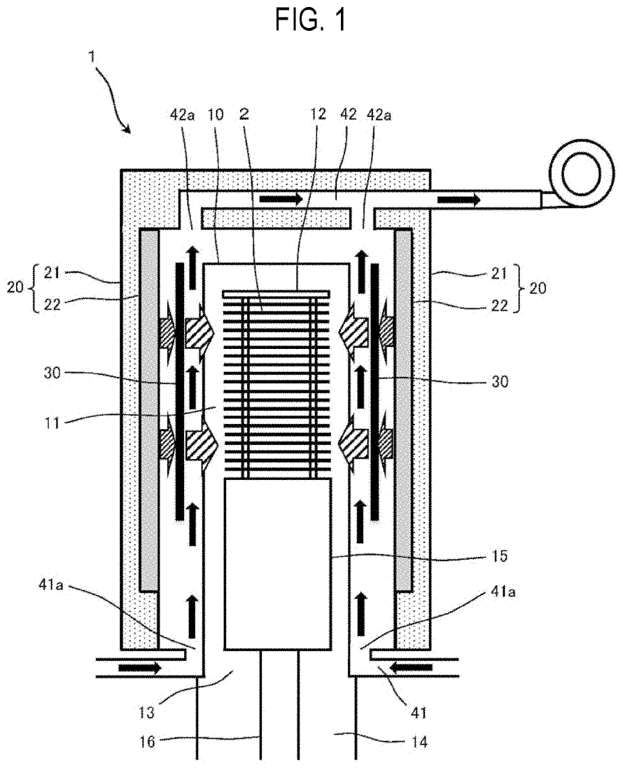

A semiconductor manufacturing apparatus 1 shown in FIG. 1 includes a process tube 10 as a vertical reaction tube. The process tube 10 is made of, for example, quartz (SiO₂), which is a heat resistant material, and is formed in a cylindrical shape with its upper end closed and its lower end opened. The process tube 10 may have a double-tube structure including an internal tube (inner tube) and an external tube (outer tube).

A process chamber 11 for processing wafers 2 is formed in an inner side of the process tube 10 (that is, in the inside of the cylindrical shape). The process chamber 11 is configured to accommodate the wafers 2 supported by a boat 12, which will be described later, in a state where the wafers 2 are arranged vertically in multiple stages. Further, a furnace opening 13 for loading/unloading the boat 12 is configured in a lower end opening of the process tube 10.

A lower chamber (load lock chamber) 14 constituting a load lock chamber for wafer transfer is arranged under the process tube 10. The lower chamber 14 is made of, for example, a metal material such as stainless steel (SUS) and is configured to form a closed space communicating with the process chamber 11 in the process tube 10 through the furnace opening 13.

In a space formed by the process tube 10 and the lower chamber 14, the boat 12 as a substrate support for supporting the wafers 2 is arranged so as to be movable in the vertical direction in the space. More specifically, the boat 12 is connected to a support rod 16 of an elevator (a boat elevator) via a heat insulating cap 15 arranged under the boat 12, and a state of the boat 12 is changed by the operation of the elevator between a state where the boat 12 is arranged in the process tube 10 (a wafer processable state) and a state where the boat 12 is arranged in the lower chamber 14 (a wafer transferable state). Further, in the state where the boat 12 is arranged in the process tube 10, the furnace opening 13 of the process tube 10 is sealed by a seal cap (not shown), whereby an airtight state in the process tube 10 is maintained. Further, the elevator for moving the boat 12 up and down may have a function as a rotator for rotating the boat 12.

The boat 12 that supports the wafers includes a pair of end plates and a plurality of holders (for example, three holders) vertically installed between the end plates. The boat 12 is configured to hold the plurality of wafers 2 in such a state that the plurality of wafers 2 are arranged horizontally with the centers of the wafers 2 aligned with each other by inserting the wafers 2 into the same end of holding grooves engraved at equal intervals in the longitudinal direction of each holder. The boat 12 is made of, for example, a heat resistant material such as quartz or SiC. Further, since the boat 12 is supported via the heat insulating cap 15 arranged under the boat 12, the boat 12 is accommodated in the process tube 10 in a state where the boat 12 is separated by an appropriate distance from a position of the furnace opening 13 where a lower end of the heat insulating cap 15 is arranged. That is, the heat insulating cap 15 is designed to insulate the vicinity of the furnace opening 13, and has a function of suppressing heat conduction downward from the boat 12 holding the wafers 2 to assist with precise wafer temperature control.

A nozzle (not shown) extending from a lower region of the process chamber 11 to an upper region thereof is provided in the process tube 10 in which the boat 12 is accommodated. The nozzle is provided with a plurality of gas supply holes arranged along the extension direction thereof. As a result, a predetermined type of gas is supplied to the wafer 2 from the gas supply holes of the nozzle. The type of gas supplied from the nozzle may be preset according to the contents of processing in the process chamber 11. For example, in the case of performing a film-forming process, a precursor gas, a reaction gas, an inert gas, etc. used for the film-forming process may be supplied to the process chamber 11, as the predetermined type of gas.

Further, an exhaust pipe (not shown) for exhausting an atmospheric gas of the process chamber 11 is connected to the process tube 10. A pressure sensor, an auto pressure controller (APC) valve, a vacuum pump, and the like are connected to the exhaust pipe, whereby an internal pressure of the process chamber 11 can be regulated.

### (2) Configuration of Heater Unit

On the outside of the process tube 10, a heater unit 20 as a heater assembly (a heating mechanism or a heating system) is arranged at a position where the heater unit 20 is concentric with the process tube 10 in order to heat the wafers 2 in the process tube 10.

The heater unit 20 includes a heat insulating case 21 arranged to cover the outer side of the heater unit 20. The heat insulating case 21 has a function of suppressing heat conduction from a heater 22, which will be described later, to the outside of the apparatus. For that purpose, the heat insulating case 21 is made of, for example, a metal material such as stainless steel (SUS) and is formed in a barrel shape, specifically a cylindrical shape, with its upper end closed and its lower end opened.

Further, the heater unit 20 includes the heater 22 as a heat generating element that generates heat, on the inner side of the heat insulating case. The heater 22 is arranged such that a heat generating surface thereof faces an outer peripheral surface of the process tube 10.

As the heater 22, it may use, for example, a lamp heater of a heating type using infrared radiation by a halogen lamp, or a resistance heater of a heating type using Joule heat by an electric resistance. However, the lamp heater is not practical because of its high cost and short life. Further, since its raising or lowering temperature rate is fast, the lamp heater has a possibility of an increase of a wafer-to-wafer (WTW) or wafer-in-wafer (WIW) temperature deviation in a temperature range of, for example, 400 degrees C. or higher. On the other hand, the resistance heater has a small WTW or WIW temperature deviation, but its temperature raising rate is slow in a low temperature range of, for example less than 400 degrees C. In particular, in the semiconductor manufacturing apparatus 1 of the present embodiment, when the resistance heater is used as the heater 22, due to that a wavelength of a radiant wave radiated from the resistance heater, a wavelength transmittable through the process tube 10 made of quartz, and a wavelength absorbed by the wafers 2, which are the objects to be processed, in the process chamber 11 are different from each other, the radiant wave does not reach the wafers 2 efficiently, and therefore, the resistance heater may need a longer heat-up time to raise the temperature than in the case of the lamp heater.

Based on the above, the semiconductor manufacturing apparatus 1 of the present embodiment uses a resistance heater as the heater 22 to thereby achieve the low cost and long life of the heater 22 and further achieve both the improvement of temperature raising performance in a low temperature range (for example, less than 400 degrees C.) and the maintenance of stable performance (an elimination of deviation) in a medium temperature range (for example, 400 degrees C. or higher, and lower than 650 degrees C.) by arranging a radiation control body 30 between the process tube 10 and the heater unit 20 and controlling a radiation intensity in a wavelength-selective manner by the radiation control body 30, as will be described in detail later.

### (3) Configuration of Radiation Control Body

The radiation control body 30 is arranged between the process tube 10, which is a reaction tube (hereinafter, also referred to as a “quartz tube”) made of quartz, and the heater 22 in the heater unit 20. Here, the radiation control body 30 is arranged in the air atmosphere between the process tube 10 and the heater 22. Further, the radiation control body 30 may be arranged in an oxygen atmosphere.

The radiation control body 30 is used to control the radiation intensity of a radiant wave radiated toward the process tube 10 in a wavelength-selective manner. More specifically, the radiation control body 30 is configured to radiate a radiant wave of a wavelength band, which is different from that of the radiant heat from the heater 22, toward the process tube 10 according to the heating from the heater 22 in the heater unit 20.

As a specific example of the radiation control body 30 that performs such wavelength conversion, one may be configured as follows.

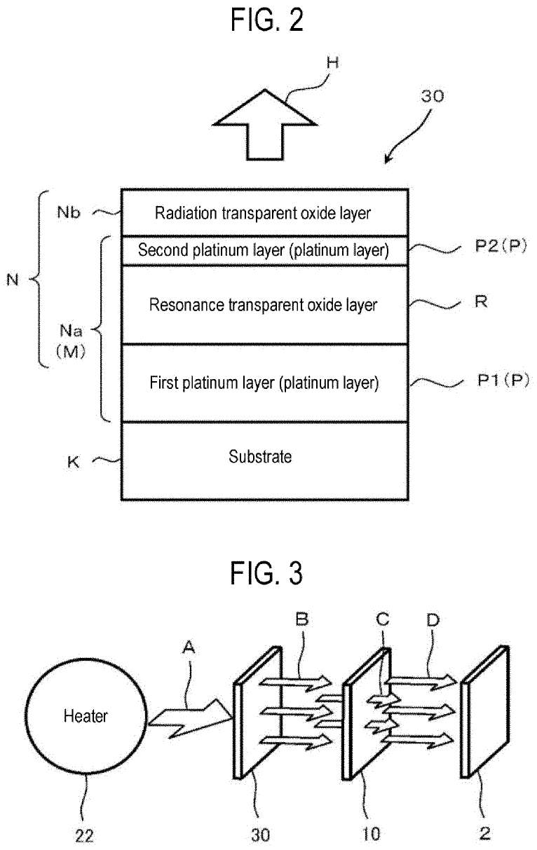

The radiation control body 30 shown in FIG. 2 is formed as a plate-shaped body arranged between the heater 22 and the process tube 10, and is configured by laminating a substrate K located on the heater 22 side and a heat radiation layer N located on the process tube 10 side.

The substrate K is configured to be in a high temperature state (for example, 800 degrees C.) by the heat from the heater 22, thereby heating the heat radiation layer N which is to be laminated thereon. The substrate K may be any one which could be in a high temperature state, and may be formed by using, for example, various heat resistant materials such as quartz (SiO₂), sapphire (Al₂O₃), stainless steel (SUS), Kanthal, nichrome, aluminum, and silicon.

When the heat radiation layer N is heated by the substrate K in the high temperature state, the heat radiation layer N is configured to radiate a radiant wave having a wavelength, which will be described in detail later, to the process tube 10 side by the heating. Therefore, the heat radiation layer N is configured by laminating a radiation controller Na and a radiation transparent oxide layer Nb, which is formed of transparent oxide such as alumina (aluminum oxide, Al₂O₃), sequentially from substrate K side. Of these, the radiation controller Na is configured to include a lamination part M of a so-called MIM (Metal Insulator Metal) structure in which a resonance transparent oxide layer R formed of transparent oxide such as alumina is located between platinum layers P as a pair of metal layers arranged along the laminating direction of the substrate K and the heat radiation layer N.

In other words, the radiation controller Na of the heat radiation layer N in the radiation control body 30 is configured to include the lamination part M including the platinum layers P, which are metal layers, and the resonance transparent oxide layer R which is an oxide layer. The lamination part M has the MIM structure in which the resonance transparent oxide layer R is located between the pair of platinum layers P. Hereinafter, regarding the pair of platinum layers P, a platinum layer P adjacent to the substrate K is referred to as a first platinum layer P1, and a platinum layer P adjacent to the radiation transparent oxide layer Nb is referred to as a second platinum layer P2. That is, the radiation control body 30 is configured such that the first platinum layer P1, the resonance transparent oxide layer R, the second platinum layer P2, and the radiation oxide layer Nb are sequentially formed from the substrate K side (that is, the heater 22 side).

Further, in the lamination part M of the MIM structure (hereinafter, also referred to as an “MIM lamination part”), the resonance transparent oxide layer R is set to be of a thickness for which a wavelength (specifically, for example, 4 μm or less) that transmitted through the process tube (quartz tube) 10 is a resonance wavelength.

In the radiation control body 30 of the above configuration, when the heat radiation layer N is heated by the substrate K in the high temperature state, the platinum layers P (the first platinum layer P1 and the second platinum layer P2) of the radiation controller Na radiate a radiant wave. At this time, the radiation rate (emissivity) of the radiant wave tends to gradually increase toward a short wavelength in a wavelength range of 4 μm or less, and maintains a low value in a wavelength range of more than 4 μm. Further, since the thickness of the resonance transparent oxide layer R of the MIM lamination part M is set to such that a wavelength of 4 μm or less, which is the wavelength transmittable through the quartz tube 10, as the resonance wavelength, the wavelength of 4 μm or less (that is, a wavelength in a narrow band below mid-infrared light) is amplified by resonance. Therefore, an amplified radiant wave H having a wavelength of 4 μm or less is emitted to the outside from the radiation transparent oxide layer Nb.

In this way, the resonance transparent oxide layer R is configured to amplify the radiant wave while repeatedly reflecting the radiant wave between the platinum layers P (the first platinum layer P1 and the second platinum layer P2). Therefore, when the thickness of the resonance transparent oxide layer R is set so that a wavelength of 4 μm or less (that is, the wavelength transmittable through the quartz tube 10) becomes the resonance wavelength, the radiant wave having the wavelength of 4 μm or less is amplified, and then, the amplified radiant wave having the wavelength of 4 μm or less is emitted to the outside. On the other hand, a radiant wave having a wavelength of more than 4 μm is emitted to the outside from the radiation transparent oxide layer Nb in a state where the radiant wave is less likely to be amplified by resonance. As a result, the radiant wave H from the radiation transparent oxide layer Nb has a large radiation rate (emissivity) in a narrow band wavelength of 4 μm or less (narrow band wavelength below mid-infrared light), and has a small radiation rate (emissivity) in a wavelength of more than 4 μm (wavelength of far-infrared light).

That is, the radiation control body 30 shown in FIG. 2 is configured to radiate mainly the radiant wave having a wavelength of 4 μm or less that is amplified by the MIM lamination part M, as the radiant wave having the wavelength transmittable through the process tube (quartz tube) 10, to the outside from the radiation transparent oxide layer Nb.

At this time, in the MIM lamination part M, the first platinum layer P1 may be configured to shield the radiant wave from the substrate K side (that is, the heater 22 side). In this way, when the first platinum layer P1 shields the radiant wave to suppress a transmission through the inside of the radiation control body 30 (particularly, the resonance transparent oxide layer R in the MIM lamination part M), the influence on the radiant wave emitted from the radiation control body 30 is suppressed.

Further, in the MIM lamination part M, the second platinum layer P2 may be configured to transmit a portion of the radiant wave from the substrate K side (that is, the heater 22 side). More specifically, the second platinum layer P2 may be configured to transmit the radiant waves having the narrow band wavelength of 4 μm or less, which is the wavelength transmittable through the process tube (quartz tube) 10. In this way, when the second platinum layer P2 transmits a portion of the radiant wave, as a result, the radiant wave having a wavelength of 4 μm or less (that is, the wavelength transmittable through the quartz tube 10) amplified by the MIM lamination part M is emitted to the outside from the radiation control body 30.

Further, the radiation transparent oxide layer Nb has a lower refractive index than the second platinum layer P2, which is a metal layer, and has a higher refractive index than air. When such the radiation transparent oxide layer Nb is arranged adjacent to the second platinum layer P2, the reflectance in the second platinum layer P2 is reduced, and as a result, the radiant wave is well emitted to the outside from the radiation control body 30.

Although the case where the radiation controller Na includes one MIM lamination part M as the heat radiation layer N is illustrated here, the radiation controller Na may include a plurality of MIM lamination parts M. Including a plurality of MIM lamination parts M means a configuration in which three or more platinum layers P are provided that are arranged along the laminating direction of the heat radiation layer N and the substrate K, and the resonance transparent oxide layers R are located between adjacent ones of the platinum layers P.

While the radiation control body 30 of the above configuration is used by being arranged between the process tube 10 and the heater 22, in the semiconductor manufacturing apparatus 1 shown in FIG. 1, the radiation control body 30 is arranged to be spaced apart from the heat generating surface (heat radiating surface) of the heater 22 in the heater unit 20. In that case, when the radiation control body 30 is arranged between the process tube 10 and the heater 22 such that a distance from the heater 22 is closer than a distance from the process tube 10, the radiation control body 30 could be efficiently heated, and cooling of the process tube 10 by a cooler (cooling unit) to be described later can be efficiently performed.

The radiation control body 30 may be arranged between the process tube 10 and the heater 22 by using a holder (not shown in FIG. 1) that supports the radiation control body 30. As the holder, one configured to suspend and support the radiation control body 30 from the upper side can be used. However, the present disclosure is not limited thereto, but the radiation control body 30 may be supported by another configuration, for example, one that supports the lower end of the radiation control body 30 on the lower side.

### (4) Configuration of Cooler (Cooling Unit)

The semiconductor manufacturing apparatus 1 shown in FIG. 1 is provided with a cooler (cooling unit) in addition to the above-described process tube 10, heater unit 20, and radiation control body 30.

The cooler is mainly used to cool the process tube 10, and is configured to include at least an introduction part 41 that introduces a cooling gas between the process tube 10 and the heater 22 in the heater unit 20, and an exhauster 42 for exhausting the introduced cooling gas. As the cooling gas, for example, an inert gas such as a N₂ gas or the atmosphere (air) such as clean air may be used. Further, components (a gas supply source, etc.) of the introduction part 41 and components (an exhaust pump, etc.) of the exhauster 42 may also be those using known techniques, and detailed explanation thereof will be omitted here.

Further, in the cooler, a gas introduction port 41a of the introduction part 41 and a gas exhaust port 42a of the exhauster 42 are arranged so that the cooling gas flows in the vicinity of the outer peripheral surface of the process tube 10 along the process tube 10. That is, the cooling gas mainly flows between the process tube 10 and the radiation control body 30 along the process tube 10.

When such a cooler is provided, it is possible to suppress the process tube 10 from being in a high temperature state by flowing the cooling gas. In particular, when the cooling gas is allowed to flow in the vicinity of the outer peripheral surface of the process tube 10, by making a flow velocity of the cooling gas in the vicinity of the outer peripheral surface the fastest, the cooling gas in the low temperature (normal temperature) state could be in contact with the process tube 10, and thus can improve the cooling efficiency.

### (5) Procedure of Basic Processing Operation

Next, an outline of the basic processing operation in the semiconductor manufacturing apparatus 1 of the above-described configuration will be described. Here, a process of manufacturing a semiconductor device, a processing operation in a case of performing a film-forming process on the wafer 2 will be given as an example.

As shown in FIG. 1, when the boat 12 is charged with a predetermined number of wafers 2, the boat 12 holding the wafers 2 is loaded into the process chamber 11 (boat loading) by the operation of the boat elevator. Then, when the operation of the boat elevator reaches the upper limit, the furnace opening 13 of the process tube 10 is sealed, so that the airtight state of the process chamber 11 is maintained in a state where the wafers 2 are accommodated.

After that, the interior of the process chamber 11 is exhausted by an exhaust pipe (not shown) and is regulated to a predetermined pressure. Further, the interior of the process chamber 11 is heated to a target temperature by utilizing the heat generated by the heater 22 in the heater unit 20 (see a hatched arrow in FIG. 1). A specific form of the heating at this time will be described in detail later. Further, the boat 12 is rotated by the boat elevator (rotator). Further, when the interior of the process chamber 11 is heated, the process tube 10 can be cooled by the cooling gas (see a black arrow in FIG. 1).

When the internal pressure and temperature of the process chamber 11 and the rotation of the boat 12 become stable as a whole, a predetermined type of gas (for example, a precursor gas) is supplied into the process chamber 11 from a nozzle (not shown). The gas supplied into the process chamber 11 flows so as to contact the wafers 2 accommodated in the process chamber 11 and then is exhausted by the exhaust pipe (not shown). At this time, in the process chamber 11, for example, a predetermined film is formed on the wafers 2 by a thermal CVD reaction caused by contact of the precursor gas with the wafers 2 heated to a predetermined processing temperature.

When a film having a desired film thickness is formed on the wafers 2 with the lapse of predetermined processing time, the supply of the precursor gas and the like is stopped, while an inert gas (purge gas) such as a N₂ gas is supplied into the process chamber 11 to substitute the internal gas atmosphere of the process chamber 11. Further, the heating by the heater 22 is stopped to lower the temperature of the process chamber 11. Then, when the temperature of the process chamber 11 is lowered to a predetermined temperature, the boat 12 holding the wafers 2 is unloaded from the process chamber 11 (boat unloading) by the operation of the boat elevator.

After that, by repeating the above-described film-forming process, a film-forming step for the wafers 2 is carried out.

In the film-forming process described above, the operations of various parts constituting the semiconductor manufacturing apparatus 1 is controlled by a controller (not shown) included in the semiconductor manufacturing apparatus 1. The controller functions as a control part (control means) of the semiconductor manufacturing apparatus 1, and is configured to include hardware resources as a computer apparatus. Then, the hardware resources execute a program (for example, a control program) or a recipe (for example, a process recipe) which is predetermined software, so that the hardware resources and the predetermined software cooperate with each other to control the above-described processing operation.

The controller as described above may be configured as a dedicated computer or a general-purpose computer. For example, the controller according to the present embodiment can be configured, for example by preparing an external memory (for example, a magnetic tape, a magnetic disk such as a flexible disk or a hard disk, an optical disc such as a CD or DVD, a magneto-optic disc such as a MO, a semiconductor memory such as a USB memory or a memory card, etc.) in which the above-mentioned program is stored, and installing the program on the general-purpose computer using the external memory. Further, a means for supplying the program to the computer is not limited to a case of supplying the program via the external memory. For example, a communication means such as the Internet or a dedicated line may be used, or information may be received from a host device via a receiver and the program may be supplied without going through the external memory.

A memory in the controller and the external memory that can be connected to the controller are configured as a non-transitory computer-readable recording medium. Hereinafter, these are collectively referred to simply as a recording medium. In addition, when the term “recording medium” is used in the present disclosure, it may include a memory alone, an external memory alone, or both of them.

### (6) Specific Example of Heat Radiation Control

Subsequently, among the series of processing operations described above, a heating process of heating the interior of the process chamber 11 by utilizing the heat generated by the heater 22 is described in more detail.

In the heating process, the radiant wave reaches the wafers 2 via the process tube 10 to raise the temperature of the wafers 2. However, in the heating process, it is required to rapidly raise the temperature of the wafers 2 from room temperature (normal temperature) to a set temperature of, for example, 300 to 400 degrees C. and to precisely control the temperature. For that purpose, it is necessary to irradiate the wafers 2 with radiation of a wavelength band which is absorbed by the wafers 2 with sufficient intensity for rapid temperature increase without raising the temperature of the process tube 10 more than necessary (for example, 400 degrees C. or higher). If the temperature of the process tube 10 is raised more than necessary (for example, when it reaches 500 degrees C. or higher), even if the heat generation from the heater 22 is stopped after the wafers 2 reaches the set temperature of, for example, 300 to 400 degrees C., there is a possibility that an overshoot situation may occur in which the temperature of the wafers 2 is continually raised due to heat transfer from the process tube 10 which has been in the high temperature state. When such an overshoot situation occurs, the time for precisely controlling the wafers 2 to reach the set temperature becomes extremely long, and as a result, the productivity of the substrate processing for the wafer 2 deteriorates.

Further, as already described, the resistance heater instead of the lamp heater may be used as the heater 22 from the viewpoint of low cost and long life of the heater 22. However, when the resistance heater is simply used as the heater 22, the radiant wave does not reach the wafers 2 efficiently, and therefore, there is a possibility that the heat-up time will be longer than in the case of the lamp heater.

Based on the above, the semiconductor manufacturing apparatus 1 of the present embodiment has a heating structure configured so that the radiation control body 30 is arranged between the process tube 10 and the heater 22 and the heat radiation control is performed by the radiation control body 30. Such a heating structure includes at least the heater 22 that emits heat, and the radiation control body 30 that performs the heat radiation control, and is configured so that the radiation control body 30 radiates the radiant wave (specifically, the radiant wave having a wavelength of 4 μm or less, which is the wavelength transmittable through the process tube 10) of a wavelength band different from the heat radiated from the heater 22, to the process tube 10. Hereinafter, a part constituting such the heating structure may be referred to as a “heat radiation device.”

Here, the heat radiation control in this heating structure is described in more detail with a case where a wafer 2 is a silicon wafer, as a specific example.

In the heating structure shown in FIG. 3, first, the heater 22 generates heat in the heating process. At this time, if the heater 22 is a resistance heater, for example, considering a wavelength band radiated from a gray body having a heating generating element temperature of about 1,100K at the time of temperature increase, the resistance heater emits a radiant wave of a wavelength band of 0.4 to 100 μm and 100 μm or more (that is, a wavelength band in a range from near-infrared, mid-infrared, to far-infrared) (see an arrow A in the figure). The radiation control body 30 is heated by this radiant wave.

When the radiation control body 30 is heated, the radiation control body 30 radiates a new radiant wave of a wavelength band, which is different from that of the heat radiated from the heater 22 by the wavelength-selective radiant intensity control, toward the process tube 10 side (see an arrow B in the figure). Specifically, the radiation control body 30 radiates, for example, a radiant wave of a narrow band wavelength of mainly 4 μm or less (a narrow band wavelength below mid-infrared light), specifically a radiant wave of a narrow band wavelength of mainly 1 μm or less (a narrow band wavelength including a near-infrared region), toward the process tube 10 side.

The radiant wave from the radiation control body 30 substantially transmits through the process tube 10 if it has a wavelength of mainly 4 μm or less (including a wavelength of 1 μm or less). In other words, if the radiant wave of a wavelength larger than 4 μm (a wavelength of far infrared light) is suppressed, absorption in the process tube 10 is less likely to occur. As a result, even when the radiant wave from the radiation control body 30 reaches, it is difficult for the process tube 10 to be heated by the radiant wave, and thus, the temperature of the process tube 10 is suppressed from being raised more than necessary (for example, 500 degrees C. or higher), and the process tube 10 transmits the reached radiant wave as it is (see an arrow C in the figure). If it is possible to suppress the temperature raise of the process tube 10 in this way, reaction products and the like adhering to an inner wall of the process tube 10 can be reduced, and as a result, it is possible to extend a cleaning cycle or a replacement cycle of the process tube 10.

At this time, when the cooler allows the cooling gas to flow, it is more effective in suppressing the temperature increase of the process tube 10.

The radiant wave (for example, the radiant wave of a narrow band wavelength of 1 μm or less, which is mainly in the near-infrared region) transmitted through the process tube 10 reaches the wafer 2 and is absorbed by the wafer 2 (see an arrow D in the figure). That is, the radiation control body 30 radiates the radiant wave of the wavelength transmittable through the process tube 10 according to the heating from the heater 22, and performs the radiation control to cause the radiant wave to reach the wafer 2 in the process tube 10.

As a result, the wafer 2 is heated to the target temperature and is adjusted to maintain that temperature. At this time, when the radiant wave having a sufficient intensity for the rapid temperature increase reaches the wafer 2, the temperature of the wafer 2 can rapidly be raised. Moreover, even in that case, since the temperature increase of the process tube 10 itself can be suppressed, there is no disadvantage due to the high temperature of the process tube 10. Therefore, even when the heater 22 is the resistance heater, it is possible to efficiently cause the radiant wave to reach the wafer 2, thereby rapidly raising the temperature of the wafer 2. Moreover, it is possible to precisely control the wafer 2 to reach a set temperature after the temperature raised.

As described above, the heating structure using the radiation control body 30 makes it possible to allow the radiant wave of the wavelength band (for example, 4 μm or less, specifically 1 μm or less) which is absorbed by the wafer 2, to reach the wafer 2 with a sufficient intensity for rapid temperature increase, without raising the temperature of the process tube 10 more than necessary (for example, 400 to 500 degrees C. or higher). Therefore, according to such a heating structure, by controlling the radiation intensity in a wavelength-selective manner by the radiation control body 30, it is possible to achieve the low cost and long life of the heater 22 and further achieve both the improvement of temperature increase performance in a low temperature range (for example, less than 400 degrees C.) and the maintenance of stable performance (the elimination of deviation) in a medium temperature range (for example, 400 degrees C. or higher, and lower than 650 degrees C.).

The heat radiation device constituting such a heating structure includes at least the heater 22 of the heater unit 20, and the radiation control body 30. That is, the heat radiation device referred to here is configured to include at least the heater 22 that emits heat to the process tube 10, and the radiation control body 30 arranged between the process tube 10 and the heater 22.

### (7) Effects of the Present Embodiment

According to the present embodiment, one or more following effects may be achieved.

(a) In the present embodiment, the radiation control body 30 is arranged between the process tube 10 and the heater 22, and the radiation control body 30 radiates the radiant wave of the wavelength transmittable through the process tube 10 by the heating from the heater 22 such that the radiant wave reaches the wafer 2 in the process tube 10. That is, the heat radiation control is performed by the radiation control body 30 between the process tube 10 and the heater 22.

Therefore, according to the present embodiment, it is possible to efficiently cause the radiant wave of the wavelength band absorbed by the wafer 2 to reach the wafer 2 without raising the temperature of the process tube 10 more than necessary. When the temperature increase of the process tube 10 itself is suppressed, there is no disadvantage due to the high temperature of the process tube 10. Further, for example, even when the heater 22 is the resistance heater, it is possible to efficiently cause the radiant wave to reach the wafer 2, thereby rapidly raising the temperature of the wafer 2. Moreover, it is possible to precisely control the wafer 2 to reach a set temperature after the temperature raised.

That is, in the present embodiment, by controlling the radiation intensity in a wavelength-selective manner by the radiation control body 30, it is possible to achieve the low cost and long life of the heater 22 and further achieve both the improvement of temperature increase performance in a low temperature range (for example, less than 400 degrees C.) and the maintenance of stable performance (the elimination of deviation) in a medium temperature range (for example, 400 degrees C. or higher, and lower than 650 degrees C.).

Therefore, according to the present embodiment, even if the wavelength of the radiant wave from the heater 22, the wavelength transmittable through the process tube 10, and the wavelength absorbed by the wafer 2 are different from each other, the processing for the wafer 2 can be performed efficiently and appropriately.

(b) In the present embodiment, the radiation control body 30 is arranged between the process tube 10 and the heater 22 in a state of being spaced apart from the heater 22. Therefore, because the radiation control body 30 can be arranged with a very simple configuration, it is possible to easily cope with the case, for example, where the radiation control body 30 is additionally arranged in the wafer heating structure in a conventional device. Further, if the radiation control body 30 is configured to be able to be attached/detached, it is possible to easily cope with the case where the radiation control body 30 is replaced as needed.

(c) In the present embodiment, the radiation control body 30 is configured to include the MIM lamination part M, and has a large radiation rate in a narrow band wavelength of 4 μm or less and a small radiation rate in a wavelength of larger than 4 μm. Therefore, it may be advantageous to radiate the radiant wave of the wavelength transmittable through the process tube 10 to reach the wafer 2 in the process tube 10.

### Second Embodiment

Next, a second embodiment of the present disclosure will be specifically described. Here, differences from the first embodiment described above will be mainly described.

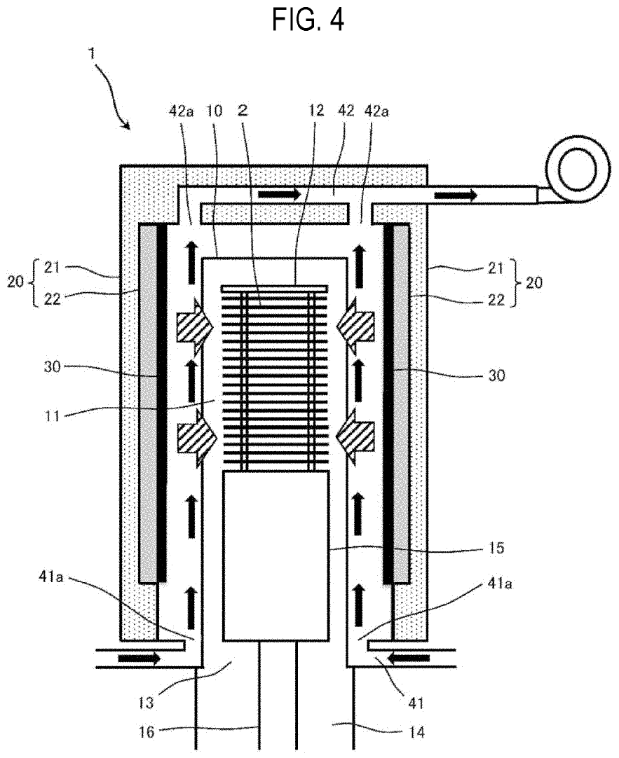

In the semiconductor manufacturing apparatus 1 shown in FIG. 4, the radiation control body 30 is installed to the heater 22 so as to cover the heat generating surface of the heater 22 in the heater unit 20.

The radiation control body 30 is formed by laminating, for example, the heat radiation layer N described in the above-described first embodiment, on the heat generating surface of the heater 22. That is, this radiation control body 30 is configured by replacing the substrate K described in the above-described first embodiment with the heat generating surface of the heater 22.

Even in a heating structure of the second embodiment using the radiation control body 30 having such a configuration, it is possible to efficiently and appropriately perform the processing for the wafer 2, as in the above-described first embodiment.

Further, in the second embodiment, since the heater 22 is configured to be accompanied with a heat radiation control function by the radiation control body 30, it is possible to perform the heat radiation control with minimized structural change compared with the above-described first embodiment. Therefore, as compared with the case where the radiation control body 30 spaced apart from the heater 22 is used as in the above-described first embodiment, it is possible to reduce the cost for heat radiation control, and it is also possible to reduce the heat capacity of the heating structure.

### <Modifications>

The embodiments of the present disclosure have been specifically described above, but the present disclosure is not limited to the above-described embodiments, and various changes can be made without departing from the gist thereof.

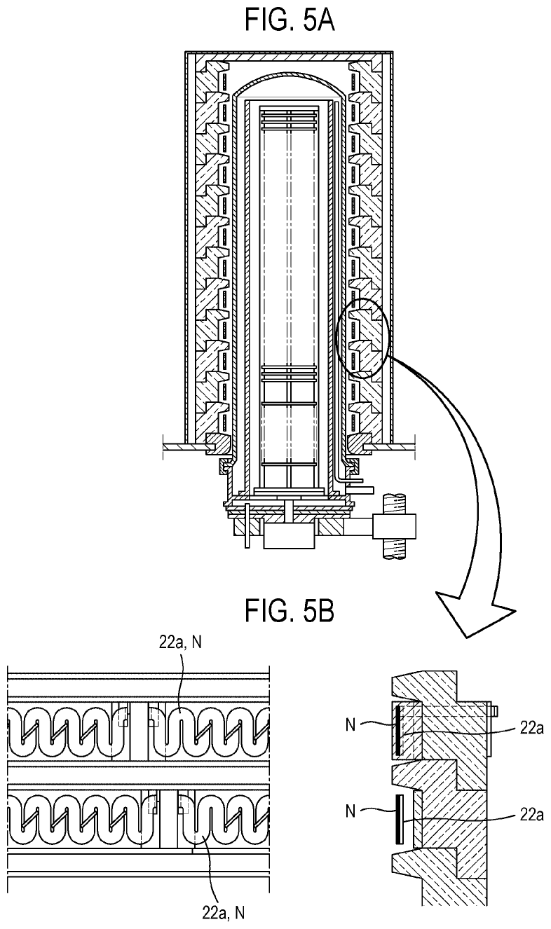

For example, the radiation control body 30 may be configured to be provided directly on a heating wire (heater wire) of the heater 22. Specifically, as shown in FIGS. 5A and 5B, the heat radiation layer N is formed on the surface of the heating wire 22a of the heater. For example, the heat radiation layer N may be formed to cover both the surface of the heating wire 22a on the reaction tube side and the surface of the heating wire 22a on the heater's heat insulator side, or only the surface of the heating wire 22a on the reaction tube side. This configuration can provide the following effects.

(1) Since a film-formed plate itself generates heat and raises the temperature, the temperature raising rate is faster than that of a plate-added structure for an indirect heating.

(2) Since the member for the plate is eliminated, the heat capacity is reduced as much. As a result, the temperature responsiveness at the time of raising or lowering the temperature is better than that of the plate addition structure.

(3) Since the direct film-forming structure requires a smaller number of parts than the plate addition structure, the parts cost and the processing cost can be reduced, and therefore, the heater can be manufactured at a relatively low cost.

Further, when a film is formed on one side facing an object to be heated and not on the other side, heat dissipation of the heater itself can be promoted to improve the responsiveness of the heater. For the film formation on only one side of the heating wire 22a, not only the cost reduction but also the responsiveness of the heating wire 22a itself can be improved.

In the above-described embodiments, a case where the film-forming process is performed on the wafer 2 is taken as an example as a process of manufacturing a semiconductor device, but the type of film to be formed is not particularly limited. For example, it is suitable for application in a case of performing a film-forming process of a metal compound (W, Ti, Hf, etc.), a silicon compound (SiN, Si, etc.), or the like. Further, the film-forming process includes, for example, a CVD, a PVD, a process of forming an oxide film or a nitride film, a process of forming a film containing metal, or the like.

Further, the present disclosure is not limited to the film-forming process, but, in addition to the film-forming process, may also be applied to other substrate processing such as heat treatment (annealing process), plasma process, diffusion process, oxidation process, nitridation process, and lithography process as long as they are performed by heating an object to be processed, containing a semiconductor.

Further, in the above-described embodiments, the semiconductor device manufacturing apparatus and the method of manufacturing the semiconductor device used in the semiconductor manufacturing process have been mainly described, but the present disclosure is not limited thereto. For example, the present disclosure is also applicable to an apparatus for processing a glass substrate such as a liquid crystal display (LCD) device, and a method of manufacturing the same.

### <Aspects of Present Disclosure>

Hereinafter, some aspects of the present disclosure will be additionally described as supplementary notes.

### (Supplementary Note 1)

According to one aspect of the present disclosure, there is provided an apparatus for manufacturing a semiconductor device, comprising:

a quartz container in which an object to be processed, which contains a semiconductor, is arranged;

a heater configured to emit heat; and

a radiation control body arranged between the quartz container and the heater,

wherein the radiation control body is configured to radiate a radiant wave of a wavelength transmittable through the quartz container by heating from the heater such that the radiant wave reaches the object to be processed in the quartz container.

### (Supplementary Note 2)

In the apparatus of Supplementary Note 1, the radiation control body is configured to have a lamination part including a metal layer and an oxide layer.

### (Supplementary Note 3)

In the apparatus of Supplementary Note 2, the radiation control body is configured to have a lamination part including an MIM structure in which an oxide layer is located between a pair of metal layers.

### (Supplementary Note 4)

In the apparatus of Supplementary Note 3, the radiation control body is configured by forming a first metal layer, a resonance oxide layer, a second metal layer, and a radiation oxide layer sequentially from a side of heater.

### (Supplementary Note 5)

In the apparatus of Supplementary Note 4, the first metal layer is configured to shield a radiant wave from the side of the heater.

### (Supplementary Note 6)

In the apparatus of Supplementary Note 4, the second metal layer is configured to transmit a portion of a radiant wave from the side of the heater.

### (Supplementary Note 7)

In the apparatus of Supplementary Note 6, the second metal layer is configured to transmit the radiant wave of the wavelength transmittable through the quartz container.

### (Supplementary Note 8)

In the apparatus of Supplementary Note 4, the resonance oxide layer is configured to amplify the radiant wave while repeatedly reflecting the radiant wave between the first metal layer and the second metal layer.

### (Supplementary Note 9)

In the apparatus of Supplementary Note 1, the radiation control body is arranged to be spaced apart from the heater.

### (Supplementary Note 10)

In the apparatus of Supplementary Note 1, the radiation control body is installed to the heater to cover a heat generating surface of the heater.

### (Supplementary Note 11)

According to another aspect of the present disclosure, there is provided a method of manufacturing a semiconductor device, comprising:

arranging an object to be processed, which contains a semiconductor, in a quartz container; and

heating the object to be processed in the quartz container by using a heater that emits heat to the quartz container, in a state where a radiation control body is interposed between the quartz container and the heater,

wherein the radiation control body radiates a radiant wave of a wavelength transmittable through the quartz container by heating from the heater such that the radiant wave reaches the object to be processed in the quartz container.

According to the present disclosure in some embodiments, it is possible to efficiently and appropriately perform a process on an object to be processed, including a semiconductor.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. An apparatus for manufacturing a semiconductor device, comprising:
a quartz container in which an object to be processed, which contains a semiconductor, is arranged;
a heater configured to emit heat; and
a radiation control body arranged between the quartz container and the heater,
wherein the radiation control body is configured to radiate a radiant wave of a wavelength transmittable through the quartz container by heating from the heater such that the radiant wave reaches the object to be processed in the quartz container.

2. The apparatus of claim 1, wherein the radiation control body is configured to have a lamination part including a metal layer and an oxide layer.

3. The apparatus of claim 1, wherein the radiation control body is configured to have a lamination part including an MIM structure in which an oxide layer is located between a pair of metal layers.

4. The apparatus of claim 3, wherein the radiation control body is configured by forming a first metal layer, a resonance oxide layer, a second metal layer, and a radiation oxide layer sequentially from a side of the heater.

5. The apparatus of claim 4, wherein the first metal layer is configured to shield a radiant wave from the side of the heater.

6. The apparatus of claim 4, wherein the second metal layer is configured to transmit a portion of a radiant wave from the side of the heater.

7. The apparatus of claim 6, wherein the second metal layer is configured to transmit the radiant wave of the wavelength transmittable through the quartz container.

8. The apparatus of claim 4, wherein the resonance oxide layer is configured to amplify the radiant wave while repeatedly reflecting the radiant wave between the first metal layer and the second metal layer.

9. The apparatus of claim 1, wherein the radiation control body is arranged to be spaced apart from the heater.

10. The apparatus of claim 1, wherein the radiation control body is installed to the heater to cover a heat generating surface of the heater.

11. A method of manufacturing a semiconductor device, comprising:
arranging an object to be processed, which contains a semiconductor, in a quartz container; and
heating the object to be processed in the quartz container by using a heater that emits heat to the quartz container, in a state where a radiation control body is interposed between the quartz container and the heater,
wherein the radiation control body radiates a radiant wave of a wavelength transmittable through the quartz container by heating from the heater such that the radiant wave reaches the object to be processed in the quartz container.
